(19) United States
(12) Patent Application Publication
(10) Pub. No.: US 2007/0116136 A1
(43) Pub. Date: May 24, 2007

(54) Digital demodulating apparatus, controlling method of the apparatus, computer program product for the apparatus, recording medium recording thereon the product, and digital receiver

(75) Inventor: Nobuyoshi Kaiki, Nara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/600,789

(22) Filed: Nov. 17, 2006

(30) Foreign Application Priority Data
Nov. 21, 2005 (JP) 2005-335325

(51) Int. Cl. H04L 27/00; H03K 7/10

(52) U.S. Cl. 375/259; 332/108

(57) ABSTRACT

A digital demodulating apparatus includes circuit elements constituting a tuner that performs channel select processing to a received signal that has been interleaved, and a demodulator that performs demodulation processing to the received signal from the tuner; a deinterleaving section that performs deinterleaving to the interleaved received signal from the tuner; and a parameter controlling section that changes the value of an operation parameter that regulates an operation of at least one of the circuit elements. The parameter controlling section determines two of the circuit elements, the quantities of changes in operation parameters of the two circuit elements, and change timings for the operation parameters of the two circuit elements, such that ranges each of which is occupied by errors to be generated in the received signal by changing the quantities of the operation parameters of the two circuit elements at the change timings for the operation parameters, do not overlap each other in the deinterleaved received signal. The parameter controlling section changes the operation parameters of the determined two circuit elements by the determined change quantities at the determined change timings.

### BACKGROUND OF THE INVENTION

1. Field of the Invention

The present invention relates to a digital demodulating apparatus that performs channel select processing and demodulation processing to a received signal that has been interleaved. The present invention relates also to a controlling method of the digital demodulating apparatus, a computer program product for the apparatus, a recording medium recording thereon the product, and a digital receiver.

2. Description of Related Art

A digital demodulating apparatus for demodulating a modulated signal, includes therein a tuner that performs channel select processing to the signal, and a demodulator that performs demodulation processing to the signal. A controller of the digital demodulating apparatus performs various controls for changing operation parameters of circuit elements that constitute the tuner and the demodulator. For example, to decrease the power consumption of a specific circuit element, the circuit element is controlled such that the power supply to the element is turned off or on.

However, some of the controls may cause errors in the signal being treated by the digital demodulating apparatus. JP-A-2001-251275 discloses a digital demodulating apparatus constructed so as to make a received signal hard to be affected by power control by turning the power of the apparatus on or off within each guard interval period.

However, the control of the digital demodulating apparatus of JP-A-2001-251275 can be performed only within each guard interval period. When the control is performed out of the guard interval period, it may bring about a problem that the reliability of information can not be ensured when the information on an image, sound, and so on, is obtained from the demodulated signal. In particular, if errors generated in the received signal concentrate temporally, information obtained from the signal becomes inaccurate.

### SUMMARY OF THE INVENTION

An object of the present invention is to provide a digital demodulating apparatus in which errors generated in a received signal when a control to change an operation parameter is performed, are hard to concentrate temporally, and therefore the reliability of information obtained from the demodulated signal is high, and also to provide a controlling method of the apparatus, a computer program product for the apparatus, a recording medium recording thereon the product, and a digital receiver.

A digital demodulating apparatus according to the present invention comprises a plurality of circuit elements that constitute a tuner that performs channel select processing to a received signal that has been interleaved, and a demodulator that performs demodulation processing to the received signal from the tuner; a deinterleaving section that performs deinterleave processing to the interleaved received signal from the tuner; and a parameter controlling section that changes the value of an operation parameter that regulates an operation of at least one of the plurality of circuit elements. The parameter controlling section determines first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section. The parameter controlling section then changes the operation parameters of the determined first and second circuit elements by the determined quantities of changes in the first and second operation parameters at the determined change timings for the first and second operation parameters.

A controlling method according to the present invention is for a digital demodulating apparatus comprising a plurality of circuit elements that constitute a tuner that performs channel select processing to a received signal that has been interleaved, and a demodulator that performs demodulation processing to the received signal from the tuner; and a deinterleaving section that performs deinterleave processing to the interleaved received signal from the tuner. The method comprises a determining step of determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section; and a parameter changing step of changing the operation parameters of the first and second circuit elements determined in the changing step, by the quantities of changes in the first and second operation parameters determined in the changing step, at the change timings for the first and second operation parameters determined in the changing step.

A computer program product according to the present invention is for a digital demodulating apparatus comprising a plurality of circuit elements that constitute a tuner that performs channel select processing to a received signal that has been interleaved, and a demodulator that performs demodulation processing to the received signal from the tuner; and a deinterleaving section that performs deinterleave processing to the interleaved received signal from the tuner. The product causes the digital demodulating apparatus to execute a determining step of determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section; and a parameter changing step of changing the operation parameters of the first and second circuit elements determined in the changing step, by the quantities of changes in the first and second operation parameters determined in the changing step, at the change timings for the first and second operation parameters determined in the changing step.

The computer program product according to the present invention can be distributed by being recorded on a computer-readable recording medium of a removable recording medium such as a compact disc read only memory (CD-ROM) disk, a flexible disk (FD), or a magneto optical (MO) disk, or a fixed recording medium such as a hard disk. Alternatively, the computer program product can be distributed by wired or wireless electrical communication means through a communication network such as the Internet. The computer program product may not be exclusive to the digital demodulating apparatus. It may be a program that cooperates with a program for channel select processing and digital demodulation processing to cause a general-purpose processor to function as the digital demodulating apparatus.

According to the present invention, when errors are generated due to changes in operation parameters, ranges each of which is occupied by errors do not overlap each other in the deinterleaved received signal. Thus, errors are hard to concentrate temporally in the received signal, and this improves the reliability of information obtained from the demodulated received signal.

According to the present invention, it is preferable that deinterleave processing to be performed by the deinterleaving section is time deinterleave processing, and the parameter controlling section determines the change timings for the first and second operation parameters such that the change timing for the first operation parameter is temporally distant from the change timing for the second operation parameter by a length not less than a time interleaving length. According to this feature, errors generated due to the changes in the operation parameters of the first and second circuit elements are hard to overlap each other in the received signal after time deinterleaving. This makes the errors hard to concentrate temporally in the received signal.

According to the present invention, it is preferable that the parameter controlling section is provided in the tuner, and the tuner receives from the demodulator information on effective symbol length and information on time interleaving length. According to this feature, because the parameter controlling section is provided in the tuner, it is convenient when an operation parameter in the tuner is changed. In addition, because information on time interleaving length obtained by the demodulator in this case, is sent to the tuner, the parameter controlling section can surely derive the time interleaving length even in the case that the parameter controlling section is provided in the tuner.

According to the present invention, it is preferable that the parameter controlling section determines the first and second circuit elements, the quantities of changes in the operation parameters, and the change timings for the operation parameters, such that the change timing for the second operation parameter is temporally precedent to the change timing for the first operation parameter, and the total quantity of errors to be included in the received signal due to the change in the operation parameter of the first circuit element decreases by the change in the operation parameter of the second circuit element. According to this feature, the total quantity of errors is decreased by changing the operation parameter of the second circuit element before changing the operation parameter of the first circuit element. Therefore, even when errors are generated due to the change in the operation parameter of the first circuit element, temporal concentration of errors in the received signal is suppressed.

According to the present invention, it is preferable that the parameter controlling section determines the first circuit element, the quantity of change in the first operation parameter, and the change timing for the first operation parameter, such that a power consumption of the first circuit element after the operation of the second circuit element is changed by the quantity of change in the first operation parameter, decreases in comparison with the power consumption of the first circuit element before the operation of the first circuit element is changed by the quantity of change in the first operation parameter. According to this feature, the power consumption of the digital demodulating apparatus is decreased.

According to the present invention, it is preferable that the parameter controlling section determines the first circuit element, the quantity of change in the operation parameter, and the change timing for the operation parameter, such that a range in the received signal that is occupied by errors generated due to the change in the first operation parameter of the first circuit element by the quantity of change in the first operation parameter, falls within one symbol included in the received signal before deinterleave processing by the deinterleaving section. According to this feature, for example, in the case of performing time deinterleave processing, the range to be occupied by errors generated due to the change in the operation parameter is within a time interleaving length, and this makes errors hard to overlap.

According to the present invention, it is preferable that the parameter controlling section is provided in the tuner, the demodulator comprises a symbol synchronization obtaining section that obtains synchronization of a symbol included in the received signal, and the tuner receives from the demodulator Information on the synchronization of the symbol obtained by the symbol synchronization obtaining section. According to this feature, because the parameter controlling section is provided in the tuner, it is convenient when an operation parameter in the tuner is changed. In addition, even when the parameter controlling section is provided in the tuner, information necessary for determining the quantity of change in the operation parameter and the change timing for the operation parameter on the basis of a symbol, can be provided to the parameter controlling section.

According to the present invention, it is preferable that the parameter controlling section determines the change timing for the first operation parameter such that the operation parameter of the first circuit element is changed at a leading edge of a symbol included in the received signal. According to this feature, the number of symbols affected by errors generated due to the change in the operation parameter can be suppressed to the minimum. For example, this minimizes the number of symbols in each of which the reliability of information in the symbol is extremely lowered.

According to the present invention, the tuner may comprise an RF amplifier section, a mixer section, a filter section, an IF amplifier section, and a VCO-PLL section, each of which comprises a plurality of circuit elements, and the parameter controlling section may select at least one of the first and second circuit elements out of the circuit elements included in the RF amplifier section, the mixer section, the filter section, the IF amplifier section, and the VCO-PLL section. According to this feature, the operation parameter is changed in a unit having a specific function in the circuit elements constituting the tuner and so on. Therefore, an effect of the change in the operation parameter and affection on the received signal are definite, and the quantity of change and the change timing can be properly determined.

According to the present invention, it is preferable that the parameter controlling section determines the second circuit element, the quantity of change in the operation parameter, and the change timing for the operation parameter, such that noises generated in the received signal in any of the RF amplifier section, the mixer section, the filter section, the IF amplifier section, and the VCO-PLL section, are decreased due to the change in the operation parameter of the second circuit element by the quantity of change in the second operation parameter by the operation parameter controlling section. According to this feature, even if errors to be generated in the signal has increased due to the change in the operation parameter of the first circuit element, the errors are decreased due to the change in the operation parameter of the second circuit element.

According to the present invention, the parameter controlling section may determine the second circuit element, the quantity of change in the operation parameter, and the change timing for the operation parameter, such that the distortion characteristic of one of the RF amplifier section, the mixer section, the filter section, the IF amplifier section, and the VCO-PLL section, is improved due to the change in the operation parameter of the second circuit element by the quantity of change in the second operation parameter. According to this feature, because conditions of the change in the operation parameter of the second circuit element is determined such that the distortion characteristic is improved, this decreases errors to be generated in the second circuit element.

According to the present invention, the operation parameter of the second circuit element may be electric power to be supplied to the second circuit element. Or, the parameter controlling section may determine the second circuit element, the quantity of change in the second operation parameter, and the change timing for the second operation parameter, such that a gain of one of the RF amplifier section and the IF amplifier section is increased due to the change in the operation parameter of the second circuit element by the quantity of change in the second operation parameter. According to this feature, because the electric power of the signal from the RF amplifier section or the IF amplifier section increases, the electric power of noises generated in the signal due to the change in the operation parameter of the first circuit element decreases relatively to the electric power of the whole of the signal from the second circuit element. This relatively decreases errors to be included in the signal due to the noises.

According to the present invention, the parameter controlling section may determine the second circuit element, the quantity of change in the second operation parameter, and the change timing for the second operation parameter, such that a mixing signal generated by the VCO-PLL section is stable in frequency due to the change in the operation parameter of the second circuit element by the quantity of change in the second operation parameter. According to this feature, the quantity of errors decreases that are generated in the signal in the tuner due to a shift of the frequency of the mixing signal by the VCO-PLL section from the original frequency. Therefore, even if errors to be included in the signal due to the change in the operation parameter of the first circuit element have increased, errors to be generated in the second circuit element decreases.

According to the present invention, the first circuit element determined by the parameter controlling section may differ in scale from the second circuit element determined by the parameter controlling section. According to this feature, circuit elements in proper scales can be determined.

According to the present invention, it is preferable that the parameter controlling section determines a third circuit element of the plurality of circuit elements, the quantity of change in a third operation parameter of the third circuit element, and a change timing for the third operation parameter of the third circuit element, such that ranges each of which is occupied by errors to be generated in the received signal by changing the operation parameters of the first and third circuit elements at the change timings for the first and third operation parameters, do not overlap each other in the received signal deinterleaved by the deinterleaving section, and ranges each of which is occupied by errors to be generated in the received signal by changing the operation parameters of the second and third circuit elements at the change timings for the second and third operation parameters, do not overlap each other in the received signal deinterleaved by the deinterleaving section, and the parameter controlling section changes the operation parameters of the determined first to third circuit elements by the determined quantities of change in the first to third operation parameters at the determined change timings for the first to third operation parameters. According to this feature, even in the case of changing the operation parameters of three of the first to third circuit elements, errors to be generated due to the changes are hard to concentrate temporally, and the reliability of information included in the received signal is improved.

According to the present invention, it is preferable that deinterleave processing to be performed by the deinterleaving section is time deinterleave processing, and the parameter controlling section determines the change timings for the first and second operation parameters such that the change timings for the first to third operation parameters are temporally distant from one another by a length not less than a time interleaving length. According to this feature, even in the case of changing the operation parameters of three of the first to third circuit elements, errors to be generated due to the changes are hard to concentrate temporally in the received signal after time deinterleaving.

According to the present invention, it is preferable that the parameter controlling section determines the first to third circuit elements, the quantities of change in the first to third operation parameters, and the change timings for the first to third operation parameters, such that (a) the change timings for the first to third operation parameters are temporally arranged in the order of the second, first, and third operation parameters; (b) the total quantity of errors to be included in the received signal due to the changes in the operation parameters of both of the first and second circuit elements, is smaller than the total quantity of errors to be included in the received signal due to the change in the operation parameter of only the first circuit element; and (c) the operation parameter of the first circuit element is returned to the operation parameter before the operation parameter of the first circuit element is changed, by changing the operation parameter of the third circuit element. According to this feature, even in the case of changing the operation parameter of the second circuit element for suppressing affection of errors generated due to the change in the operation parameter of the first circuit element, the operation parameter of the second circuit element is returned to the original state by changing the operation parameter of the third circuit element. Thus, the power consumption is returned to the original state, and this prevents waste power consumption.

### BRIEF DESCRIPTION OF THE DRAWINGS

Other and further objects, features and advantages of the invention will appear more fully from the following description taken in connection with the accompanying drawings in which:

FIG. 1A is an external view of a handheld terminal according to an embodiment of the present invention;

FIG. 1B is a block diagram showing a general construction of a digital demodulating apparatus included in the terminal of FIG. 1A;

FIG. 2 is a block diagram showing a construction of a tuner included in the apparatus of FIG. 1B;

FIG. 3 is a representation showing an example of interleaving and deinterleaving performed and to be performed to a signal received by the tuner of FIG. 2;

FIG. 4A is a block diagram showing a construction of a demodulator included in the apparatus of FIG. 1B;

FIG. 4B is a block diagram showing a construction of a deinterleaving section included in the demodulator of FIG. 4A;

FIG. 4C is a block diagram showing a construction of a decoder included in the demodulator of FIG. 4A;

FIG. 5 is a block diagram showing a construction of a tuner controller included in the tuner of FIG. 2;

FIGS. 6A and 6B are timing charts showing errors included in a signal Si or Sd when operation parameters of two circuit elements are changed that are included in the tuner and the demodulator of FIG. 1B according to the embodiment of the present invention;

FIG. 7 is a timing chart showing errors included in a signal Si or Sd when operation parameters of three circuit elements are changed that are included in the tuner and the demodulator of FIG. 1B according to another embodiment of the present invention; and

FIGS. 8A and 8B are timing charts showing errors included in a signal Si or Sd when operation parameters are changed that are according to another embodiment than the embodiments of the changes in the operation parameters of the circuit elements included in the tuner and the demodulator shown in FIGS. 6A, 6B, and 7.

### DESCRIPTION OF THE PREFERRED EMBODIMENTS

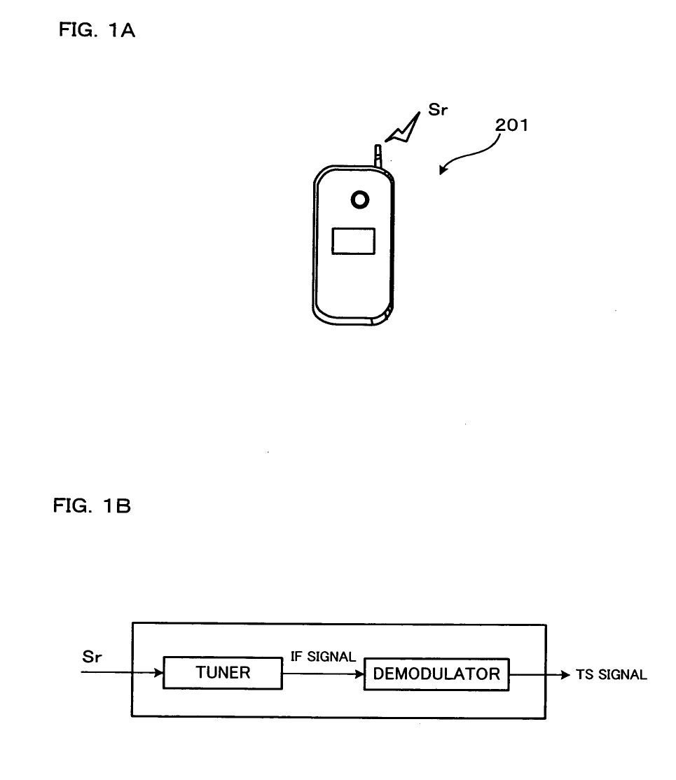

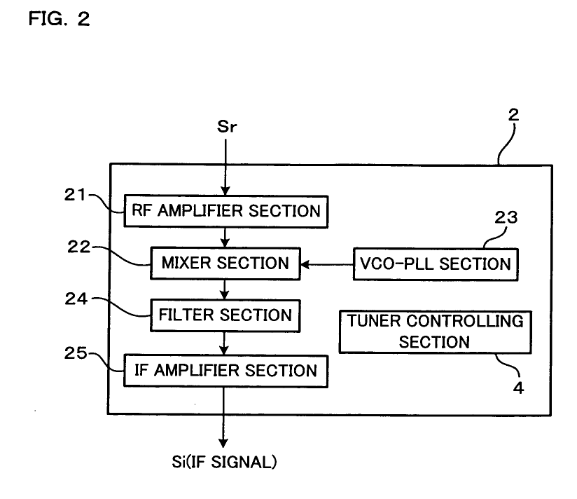

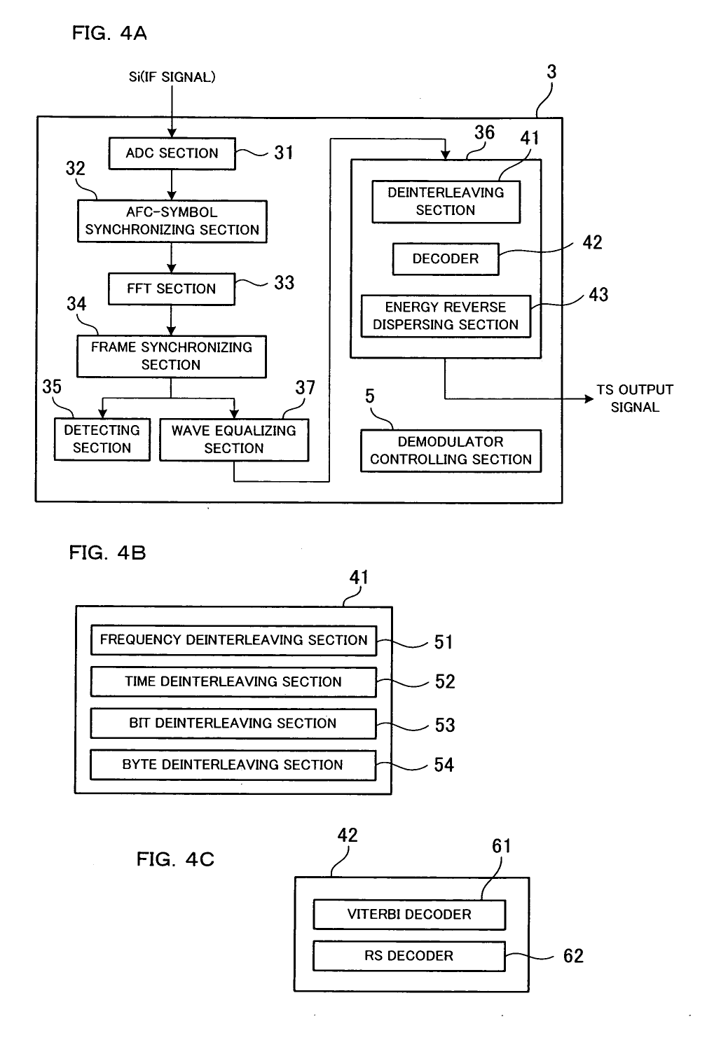

Hereinafter, a digital demodulating apparatus according to an embodiment of the present invention will be described. FIG. 1B shows a general construction of the digital demodulating apparatus 1. In this specification, a “circuit element” means a circuit element that constitutes a tuner, or a circuit element that constitutes a demodulator. More specifically, the “circuit element” can correspond to any unit part, for example, a circuit that constitutes each section of the tuner 2 shown in FIG. 2; a circuit that constitutes each section of the demodulator 3 shown in FIG. 4A; or a circuit element equivalent to one transistor that constitutes one of the circuits. In addition, “the number of parts included in a circuit element” corresponds to, for example, the number of parts equivalent to transistors that constitute a section of the demodulator 3. That is, when comparing the number of parts, the numbers of parts in the same degree are compared with each other.

The digital demodulating apparatus 1 of this embodiment is provided in a cellular phone 201 as a digital receiver, as shown in FIG. 1A. A signal Sr received by the cellular phone 201 through its antenna is demodulated by the digital demodulating apparatus 1. Information on data of characters, an image, sounds, and a program, is taken out from a demodulated signal output from the digital demodulating apparatus 1. The characters, image, sounds, and program, are then reproduced from the information to be provided to a user of the cellular phone 201 through a not-shown display and a not-shown speaker provided on the phone 201. Note that the digital demodulating apparatus 1 may be adopted in another digital receiver than such a cellular phone, for example, a digital television receiver, a wireless LAN device, or a personal computer using wireless LAN.

The digital demodulating apparatus 1 includes therein a tuner 2 and a demodulator 3. The tuner 2 is electrically connected to the demodulator 3. The tuner 2 is also electrically connected to an antenna and so on to receive a signal through the antenna and so on. The tuner 2 amplifies the received signal Sr and convert it into an intermediate frequency (IF) signal Si, which is sent to the demodulator 3. The demodulator 3 receives the IF signal sent from the tuner 2, demodulates the IF signal, and outputs the demodulated signal. When the ISDB-T system as will be described later, is adopted, the demodulated signal from the demodulator 3 is a transport stream (TS) signal.

Each circuit element that constitutes the tuner 2 and the demodulator 3, may be a circuit made up of a plurality of circuit elements constructed so as to serve each function; or may be realized by general-purpose CPU, RAM, etc., and a computer program that makes the CPU operate so as to serve each function as will be described later. In the latter case, a tuner controlling section 4, a demodulator controlling section 5, an FFT section 33, etc., as will be described later, are realized by combining the hardware such as the CPU and the computer program.

[Tuner]

Next, the tuner 2 will be described. FIG. 2 is a block diagram showing a construction of the tuner 2.

The tuner 2 includes therein an RF amplifier section 21, a mixer section 22, a VCO-PLL section 23, a filter section 24, and an IF amplifier section 25. The signal Sr received by the tuner 2 is amplified by the RF amplifier section 21, and then sent to the mixer section 22. The VCO-PLL section 23 generates a mixing signal based on a frequency corresponding to a specific channel, which is channel select processing. The mixing signal generated by the VCO-PLL section 23 is sent to the mixer section 22. The mixer section 22 mixes the signal Sr sent from the RF amplifier section 21 and the mixing signal sent from the VCO-PLL section 23 to generate an IF signal Si according to an IF frequency.

The IF signal generated by the mixer section 22 is sent to the filter section 24. The filter section 24 removes unnecessary signal components from the IF signal sent from the mixer section 22. The IF signal from which the unnecessary signal components have been removed, is sent to the IF amplifier section 25, amplified by the IF amplifier section 25, and then sent to the demodulator 3.

A tuner controlling section 4 is provided in the tuner 2. The tuner controlling section 4 controls each section of the tuner 2 such as the RF amplifier section 21, as will be described later.

[Received signal]

Next, the received signal received by the tuner 2 will be described. As an example of this embodiment, a case will be described wherein a transmission system according to Japanese digital terrestrial broadcasting is adopted for the transmission of the signal Sr. In this case, the signal Sr received by the tuner 2 is according to the integrated services digital broadcasting-terrestrial (ISDB-T) system. As the transmission method for the ISDB-T system, the orthogonal frequency division multiplexing (OFDM) method is adopted.

For the received signal of the digital demodulating apparatus according to this embodiment, other than the ISDB-T system as described above, the digital audio broadcasting (DAB) system, the digital video broadcasting-terrestrial (DVB-T) system, or the digital video broadcasting-handheld (DVB-H) system in Europe; the digital multimedia broadcasting (DMB) system in Korea; or the IEEE802.11a/b/g/n system used for a wireless LAN may be adopted. Further, the present invention may be applied to a cable television system or the like with no antenna, which receives a signal for which the OFDM method is adopted.

The OFDM method is a transmission method as follows. This method is a multicarrier method in which a plurality of carrier waves different in frequency are used for data transmission. The carrier waves used in the OFDM method have their wave forms orthogonal to each other. Here, “two waves are orthogonal” means that the value is zero when the functions each representing the amplitude of the wave to time are multiplied by each other and then temporally integrated in an integration region corresponding to one cycle, that is, the inner product of the functions is zero.

Upon data transmission, the carrier waves are modulated (or mapped) in accordance with each value of data to be transmitted. A plurality of carrier waves thus modulated (or mapped) are superimposed. Thus, an OFDM signal is generated by modulating the carrier waves in accordance with data values and superimposing a number of modulated carrier waves. In the OFDM method, thus generating an OFDM signal is equivalent to performing inverse Fourier transform. In the below description, an effective symbol length corresponds to the inverse of a frequency separation of carrier waves used in the OFDM method.

In order to eliminate affection of delayed waves other than a direct wave, a guard interval is inserted in the modulated signal in which a plurality of carrier waves modulated as described above are superimposed. The guard interval is made in the manner that one end of a signal of each effective symbol length of the modulated signal is copied and inserted to the other end of the signal of the effective symbol length. The modulated signal into which the guard interval has been inserted, is transmitted as an OFDM signal.

The signal made up of the signal of an effective symbol length and a guard interval is referred to as one symbol. The OFDM signal is constructed as a series of a plurality of symbols. When a signal is received in which the OFDM signal and a delayed wave that reaches the reception side with being delayed in time, are superimposed, the received signal includes therein a portion. in which signals included in different symbols are superimposed. The guard interval is used for taking out a portion other than the portion in which the signals are superimposed.

In digital terrestrial broadcasting, encoding is performed to the data to be transmitted by the OFDM signal in order to correct errors caused by noise and interference waves generated in the transmission path. For encoding used are Reed-Solomon (RS) coding and Viterbi coding. In the RS coding used in digital terrestrial broadcasting, the later 16 bytes of the data of 204 bytes to be transmitted serve as check bits, and an error of eight bytes of 204 bytes can be corrected at the maximum.

In the Viterbi coding, the coding rate k/n is standardized to ½ to ⅞ where n represents the number of bits of encoded data to be transmitted and k represents the number of bits of data before encoding. To restore the data that has been RS-encoded and Viterbi-encoded, RS decoding and Viterbi decoding are performed on the reception side.

In accordance with conditions of a transmission path, there is a case wherein burst error arises in which errors concentrate temporally or in frequency in a transmitted signal. On the other hand, when errors can not be corrected after Viterbi decoding to restore a Viterbi-coded signal, in general, there are many cases wherein burst error arises. In the case that errors generated in a signal of a certain length are to be corrected by error correction using RS decoding, there is a limit in the number of errors that can be corrected in the signal of the length. Therefore, if the burst error as described above arises, there may be a case wherein error correction is impossible.

In digital terrestrial broadcasting, various kinds of interleave processing are performed to data to be transmitted by transmitted signals, in order to make error correction possible even if burst errors arise in the transmitted signals. As the interleave processing, there are known bit interleave processing, byte interleave processing, time interleave processing, and frequency interleave processing. The interleave processing as described above is to rearrange temporally or in frequency, data corresponding to signals included in a transmitted signal. In particular, time interleave processing and so on are used for temporally rearranging a plurality of signals successive temporally. Frequency interleave processing is used for rearranging in frequency at random, a plurality of carrier waves continuous in frequency. For example, time interleave processing and time deinterleave processing for restoring time-interleaved data, are performed as follows.

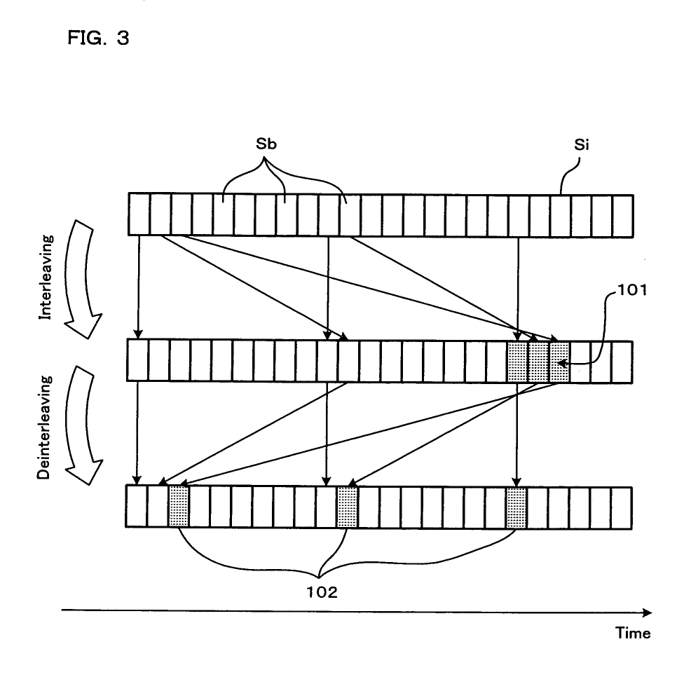

FIG. 3 is a representation showing an example of time interleave and deinterleave processing. FIG. 3 shows three signals Si before and after interleave and deinterleave processing. As shown in FIG. 3, each signal is constituted by a plurality of symbols Sb successive temporally.

An OFDM signal Sr constituted by a plurality of modulated carrier waves is rearranged by time interleave processing in a predetermined order in a unit of data corresponding to the length of each symbol Sb, as shown in FIG. 3. The signal corresponding to the data thus rearranged is transmitted from a transmitter. A burst error 101 arises in part of the signal in accordance with conditions of the transmission path from the transmitter to a receiver. After the receiver receives the signal, time deinterleave processing is performed on the receiver side. Data once rearranged by time interleave processing is restored to its original order by time deinterleave processing. By this, the burst error 101 having arisen over a plurality of symbols in the transmission path is dispersed to errors 102 of the respective symbols by time deinterleave processing.

As shown in FIG. 3, rearranging is performed by time interleave processing such that each symbol is shifted to a position temporally later than its original position before time interleave processing. In addition, signals of symbols included in carrier waves different in frequency are included in temporally different positions in the signal after rearrangement, respectively.

As described above, even when a burst error arises in which errors concentrate temporally, error correction is possible because the errors are dispersed after time deinterleave processing.

In byte interleave processing, a signal is rearranged in a unit of byte such that data is dispersed in a range of 204 bytes of RS coding. In bit interleave processing, a signal is rearranged in a unit of bit. In frequency interleave processing, symbols are rearranged over carrier waves included in a signal Sr.

In digital terrestrial broadcasting, in addition to the above, energy dispersal processing is performed to prevent energy bias in a transmitted signal due to data bias. In the energy dispersal processing, data is made random by implementing an exclusive OR operation in a unit of bit between pseudorandom data and data to be transmitted.

[Demodulator]

Next, the demodulator 3 will be described. FIG. 4A is a block diagram showing a construction of the demodulator 3. As shown in FIG. 4A, the demodulator 3 is made up of a plurality of parts such as an ADC section 31 as described below.

The demodulator 3 includes therein an ADC section 31, an AFC-symbol synchronizing section 32, a fast Fourier transform (FFT) section 33, a frame synchronizing section 34, a detecting section 35, a wave equalizing section 37, and an error correcting section 36. The demodulator 3 performs demodulation processing and error correction processing to an IF signal.

An IF signal sent from the tuner 2 is input to the ADC section 31. The ADC section 31 converts the input analogue IF signal into a digital signal, and sends the converted digital signal to the AFC-symbol synchronizing section 32. The AFC-symbol synchronizing section 32 performs correction processing such as filter processing to the digital signal sent from the ADC section 31. The AFC-symbol synchronizing section 32 determines the start point of Fourier transform by the FFT section 33 as will be described later, that is, a symbol synchronization point. The AFC-symbol synchronizing section 32 then sends the synchronized digital signal to the FFT section 33. In addition, the AFC-symbol synchronizing section 32 sends information on the symbol synchronization point to the tuner controlling section 4. Further, the AFC-symbol synchronizing section 32 derives information on a mode indicating an effective symbol length, and sends the information to the tuner controlling section 4. In this embodiment, modes indicating effective symbol lengths include a mode 1 of an effective symbol length of 252 microseconds, a mode 2 of an effective symbol length of 504 microseconds, and a mode 3 of an effective symbol length of 1008 microseconds.

When a symbol synchronization point is determined, a point that makes it possible to realize the most suitable reception having the least affection of a delayed wave reaching with a delay, and so on, is set to the synchronization point. As a method of determining the synchronization point, a method in which correlation of signals is referred to; a method in which phase shift is corrected by using a pilot signal; or the like, is used.

The FFT section 33 converts by Fourier transform, that is, by time-frequency transform, the digital signal sent from the AFC-symbol synchronizing section 32. For this Fourier transform, so-called fast Fourier transform (FFT) is used in general. Because the digital signal is an OFDM signal, it has its waveform that has been converted by inverse Fourier transform, that is, its waveform in which a plurality of carrier waves modulated in accordance with data values are superimposed. The FFT section 33 takes out the plurality of carrier waves modulated in accordance with data values, from the thus superimposed wave. The FFT section 33 then rearranges digital signals corresponding to data values distributed to the respective carrier waves, so that the signals are temporally arranged in the original order of data. The FFT section 33 thereby reproduces a digital signal corresponding to data before generation of the OFDM signal. The FFT section 33 then sends the digital signal to the frame synchronizing section 34.

The frame synchronizing section 34 synchronizes the digital signal sent from the FFT section 33, in a unit of frame. One frame is constituted by, for example, 204 symbols, and a batch of TMCC information is obtained from one frame signal. The digital signal synchronized by the frame synchronizing section 34 is sent to the wave equalizing section 37 and also to the detecting section 35.

On the basis of a scattered pilot signal or the like included in the digital signal, the wave equalizing section 37 performs wave equalization processing to the digital signal that has been synchronized by the frame synchronizing section 34. After correcting the signal by wave equalization, the wave equalizing section 37 demodulates (or demaps) the signal into a digital signal corresponding to data values, and then sends the demodulated (or demapped) digital signal to the error correcting section 36. In addition, on the basis of the scattered pilot signal or the like included in the digital signal, the wave equalizing section 37 derives the difference between the constellation of each equalized carrier wave and a specified value.

The detecting section 35 takes out TMCC information included in the digital signal. The detecting section 35 sends the information on TMCC to the tuner controlling section 4. The TMCC information contains therein information on a transmission system such as a modulation method for carrier waves, such as 64QAM, 16QAM, or QPSK; a convolution coding rate of, for example, ½, ⅔, ¾, ⅚, or ⅞; and so on. As the guard interval lengths adopted are ¼, ⅛, 1/16, and 1/32 of the length of an effective symbol.

As shown in FIG. 4A, the error correcting section 36 includes therein a deinterleaving section 41, a decoder 42, and an energy reverse dispersing section 43. The deinterleaving section 41 performs deinterleave processing to the demodulated signal sent from the wave equalizing section 37. As shown in FIG. 4B, the deinterleaving section 41 includes therein a frequency deinterleaving section 51, a time deinterleaving section 52, a bit deinterleaving section 53, and a byte deinterleaving section 54. The deinterleaving sections 51 to 54 perform various kinds of deinterleaving processing as described above, respectively. The demodulated signal to which various kinds of interleave processing have been performed is restored by the above kinds of deinterleave processing to the demodulated signal before interleaving.

The decoder 42 decodes the demodulated signal sent from the wave equalizing section 37. As shown in FIG. 4C, the decoder 42 includes therein a Viterbi decoder 61 and an RS decoder 62. The decoders 61 and 62 perform Viterbi decoding and RS decoding as described above, respectively. By the decoding processing, the demodulated signal to which Viterbi coding and RS coding have been performed is restored to the demodulated signal before coding.

The energy reverse dispersing section 43 restores the demodulated signal sent from the detecting section 35, to the demodulated signal before energy dispersal.

These kinds of deinterleaving, decoding, and energy reverse dispersing are performed in an order corresponding to the order in which the kinds of interleaving, encoding, and energy dispersing were performed on the transmission side. In the case of ISDB-T demodulation, processing is performed in the order of frequency deinterleaving, time deinterleaving, bit deinterleaving, Viterbi decoding, byte deinterleaving, energy reverse dispersal, and RS decoding.

A demodulator controlling section 5 is provided in the demodulator 3. The demodulator controlling section 5 changes operation parameters in circuit elements of the demodulator 3, as will be described later.

[Change in Operation Parameter by Tuner Controlling Section]

Next, change in operation parameter of the tuner 2 by the tuner controlling section 4 will be described. In the below, three of first to third embodiments of change in operation parameter of the tuner 2 by the tuner controlling section 4 will be described in this order. In the below description, it is mainly supposed that each of the RF amplifier section 21, the mixer section 22, the filter section 24, the IF amplifier section 25, and the VCO-PLL section 23 is constituted by circuit elements.

### First Embodiment

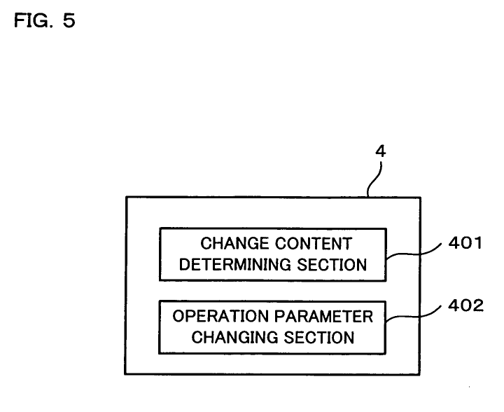

As shown in FIG. 5, the tuner controlling section 4 includes therein a change content determining section 401 and an operation parameter changing section 402. The change content determining section 401 and the operation parameter changing section 402 perform controls to change various operation parameters in the tuner 2. For example, they change an operation parameter for the power consumption of the VCO-PLL section 23 to decrease the power consumption of the VCO-PLL section 23 and so on. Thus, an operation parameter is a parameter that regulates an operation of each circuit element.

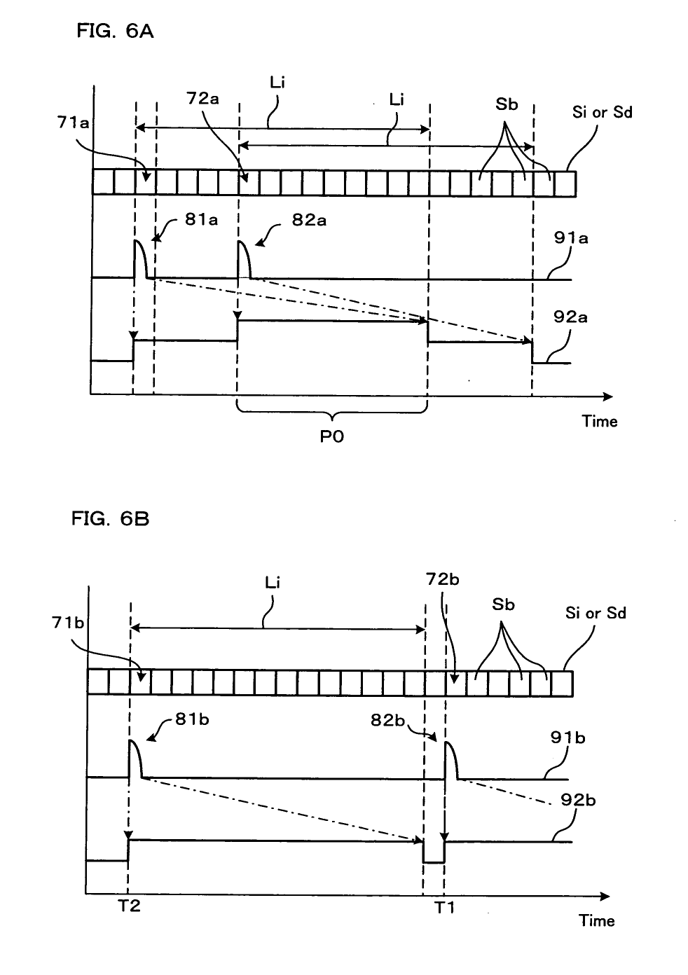

The tuner 2 receives a signal Sr in which errors caused by various factors on the transmission path have been added. Further, errors caused by various factors in the tuner 2 are added in the signal Sr received by the tuner 2, and the resultant signal Si is output from the tuner 2. In FIG. 6A, a curved line 91a represents the quantity of such errors included in the signal Si. Errors are generated in the signal Si even when an operation parameter of the tuner 2 has been changed, for example, the power consumption of the VCO-PLL section 23 has been changed, as described above. The curved line 91a shows errors 81a and 82a generated at positions corresponding to respective symbols 71a and 72a of the signal Si due to a change in such an operation parameter. In the case of FIGS. 6A and 6B, it is supposed that affection of an error falls within one symbol.

Such errors included in the signal Si are dispersed by deinterleave processing by the deinterleaving section 41, as described above. A curved line 92a represents the quantity of errors included in the signal Sd, which have been dispersed by, for example, time deinterleaving. Each of the errors 81a and 82a is dispersed over the range of a time interleaving length Li. As shown in FIG. 6A, however, the ranges overlap in which the respective errors 81a and 82a are dispersed. In the period P0 in which the ranges overlap, the signal Sd includes errors more than errors in the period in which the dispersion ranges do not overlap. When a range in which errors have temporally concentrated thus exists in the deinterleaved signal Sd, the errors may not completely be corrected even after the error correcting section 36 performed processing to correct the errors. When the errors in the signal Sd were not fully corrected, information included in the signal after the error correction is low in reliability. Therefore, to improve the reliability of information included in the signal Si, the ranges in which errors have been dispersed are made not to overlap in the signal Sd after deinterleave processing.

The ranges in which errors have been dispersed overlap after time deinterleaving as described above because the errors 81a and 82a are temporally close to each other. In time deinterleave processing, as shown in FIGS. 6A and 6B, errors are dispersed temporally backward in the range of a time interleaving length. Thus, to prevent the dispersion ranges from overlapping, as shown in FIG. 6B, it suffices if the errors 81b and 82b are temporally distant from each other by a length not less than a time interleaving length. A curved line 91b represents the quantity of errors included in the signal Si before time deinterleaving, and a curved line 92b represents the quantity of errors included in the signal Sd after time deinterleaving.

For this purpose, the change content determining section 401 in the tuner controlling section 4 first determines first and second circuit elements whose operation parameters are to be changed. More specifically, one of the RF amplifier section 21, the mixer section 22, the VCO-PLL section 23, the filter section 24, and the IF amplifier section 25, is selected as each of the first and second circuit elements. Next, the change content determining section 401 determines the quantity of change in operation parameter of the selected two circuit elements. For example, the change content determining section 401 decides that the power consumption of the whole of the RF amplifier section 21 and the VCO-PLL section 23 is decreased by 10% from the power consumption before change.

Further, the change content determining section 401 determines timings at which the operation parameters of the selected two circuit elements are to be changed, such that the timings are temporally distant from each other by a length not less than a time interleaving length. For example, the change timings for the operation parameters of the two circuit elements are determined as a change timing T1 for one circuit element in which the error 81b is generated on the symbol 71b, and a change timing T2 for the other circuit element in which the error 82b is generated on the symbol 72b. As shown in FIG. 6B, the timings T1 and T2 are temporally distant from each other by a length not less than a time interleaving length Li.

Each of the timings T1 and T2 is set so as to be at the leading edge of the corresponding one of the symbols 71b and 72b. That is, the change content determining section 401 determines each change timing for an operation parameter such that the timing is at the leading edge of a symbol. This can minimize the number of symbols affected by errors generated due to the change in the operation parameter.

The operation parameter changing section 402 of the tuner controlling section 4 changes the operation parameters of the two circuit elements determined by the change content determining section 401, at the timings determined by the change content determining section 401, by the quantities of change determined by the change content determining section 401. For example, the operation parameter changing section 402 changes the power consumptions of the RF amplifier section 21 and the VCO-PLL section 23 by 10% at the respective timings T1 and T2. The time interleaving length is derived from TMCC information and mode information sent from the demodulator 3. That is, the TMCC information contains information on the number of symbols included in the signal of a time interleaving length, and a guard interval length, and an effective symbol length is obtained from the mode information. The time interleaving length is then derived from the number of symbols, the effective symbol length, and the guard interval length.

Thereby, the ranges in which errors have been dispersed are made not to overlap in the signal Sd after deinterleave processing. Thus, the errors do not temporally concentrate, and this can improve the reliability of information included in the signal Si.

Each of the RF amplifier section 21, the mixer section 22, the VCO-PLL section 23, the filter section 24, and the IF amplifier section 25, is constituted by a circuit made up of a plurality of circuit elements including a circuit equivalent to a transistor or the like. The object to be changed in operation parameter determined by the change content determining section 401 may be in a unit of the whole of a circuit constituting the RF amplifier 21 or the like, or may be some circuit elements included in the circuit. For example, while a change in operation parameter of the RF amplifier section 21 is a decrease in the electric power to be supplied to the whole of the RF amplifier section 21, a change in operation parameter of the VCO-PLL section 23 is implemented to a frequency generator that is made up of part of the circuit elements included in the VCO-PLL section 23. Thus, two circuit elements determined by the change content determining section 401 may be different in scale. The “difference in scale of circuit element” means the difference in one or both of the number of parts constituting the circuit element and the size of the circuit element. By thus differing in scale of circuit element, a second circuit element can be determined that is proper in scale to a first circuit element.

In the above example, it is supposed that a change in operation parameter causes generation of errors in the signal Si. However, the change content determining section 401 determines the change timing for the operation parameter and so on as described above, irrespective of whether or not the change in the operation parameter causes generation of errors. Thereby, the judgment whether or not errors are generated is not needed, and an operation parameter is changed such that errors are always hard to concentrate temporally.

### Second Embodiment

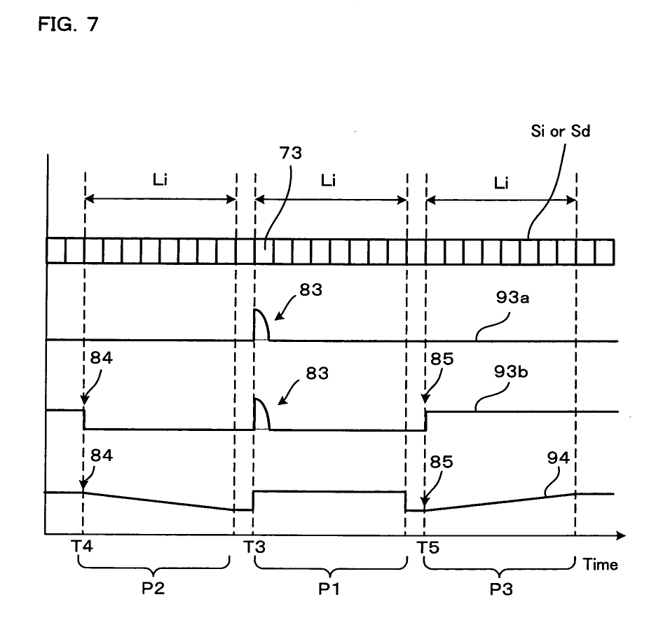

Next, a second embodiment of a change in an operation parameter by the tuner controlling section 4 will be described. FIG. 7 shows errors and so on generated in the signal Si due to a change in an operation parameter according to the second embodiment. In FIG. 7, an error 83 generated due to a change in an operation parameter falls within one symbol 73.

The change content determining section 401 determines first to third circuit elements as objects to which an operation parameter is to be changed. The circuit elements are selected out of the RF amplifier section 21, the mixer section 22, the VCO-PLL section 23, the filter section 24, and the IF amplifier section 25, included in the tuner 2, and sections included in the demodulator 3, as shown in FIGS. 4A to 4C. The change content determining section 401 then determines the quantity of the change in an operation parameter in each of the first to third circuit element. For example, the change content determining section 401 selects the RF amplifier section 21 as the first circuit element, and determines a decrease in power consumption by 10% as the quantity of the change in an operation parameter.

As described above, the change in the operation parameter may cause generation of errors in the signal Si. In FIG. 7, a curved line 93a represents the quantity of errors included in the signal Si before deinterleaving, due to the change in the operation parameter. The curved line 93a includes an error 83 generated due to the change in the operation parameter. To prevent the reliability of information included in the signal Si from decreasing due to such errors, the first to third circuit elements and the change timings are determined in this embodiment as follows.

First, the change content determining section 401 determines a first circuit element. Next, the change content determining section 401 determines as a second circuit element a circuit element and the quantity of a change in an operation parameter such that changing the operation parameter decreases errors to be included in the signal Si. For example, the change content determining section 401 selects the RF amplifier section 21 as the second circuit element, and determines the quantity of a change in an operation parameter of the second circuit element such that the gains of the RF amplifier section 21 and the IF amplifier section 25 increase. Because the electric power of the signal Si increases thereby, the electric power of noise to be generated in the signal Si due to the change in the operation parameter of the first circuit element reduces relatively to the electric power of the whole of the signal. Therefore, errors relatively decreases that is to be included in the signal Sd due to such noise.

In another example, the change content determining section 401 selects as a second circuit element a circuit element that constitutes the VCO-PLL section 23, and determines the quantity of a change in an operation parameter of the second circuit element such that the frequency of a mixing signal by the VCO-PLL section 23 is more stable. Thereby, the quantity of errors decreases that are generated due to the deviation of the frequency of the mixing signal by the VCO-PLL section 23 from its original frequency when the IF signal is generated in the tuner 2. Thus, the total quantity of errors decreases that are included in the signal Si due to the change in the operation parameter of the first circuit element.

A change in the operation parameter to increase the gain of the RF amplifier section 21, or a change in the operation parameter to stabilize the frequency of the mixing signal in the VCO-PLL section 23, as described above, increases the power consumption of the circuit element whose operation parameter is changed.

In general, an increase in electric power, i.e., current or voltage, to be supplied to a circuit element, for example, to increase its gain, makes it possible to decrease noise generated in the circuit or decrease distortion of an output signal even when a more intense signal is inputed. For this reason, one of the RF amplifier section 21, the mixer section 22, the filter section 24, the IF amplifier section 25, and the VCO-PLL section 23 is selected as the second circuit element, and the quantity of a change in supply power by a change in supply current or supply voltage is determined as an operation parameter. Thereby, noise to be generated in the circuit element selected out of the RF amplifier section 21, the mixer section 22, the filter section 24, the IF amplifier section 25, and the VCO-PLL section 23, is reduced in itself, and this decreases the quantity of errors to be generated when the IF signal is generated in the tuner 2. Or, the linearity of the output signal to the input signal in the circuit element selected out of the RF amplifier section 21, the mixer section 22, the filter section 24, the IF amplifier section 25, and the VCO-PLL section 23, is improved in itself, and this decreases the quantity of errors to be generated when the IF signal is generated in the tuner 2. Therefore, errors decreases that are included in the signal Sd due to the change in the operation parameter of the first circuit element.

Further, by a method other than a method in which the electric power such as current or voltage to be supplied to a circuit element is increased, the quantity of errors to be generated when the IF signal is generated in the tuner 2 may be decreased. For example, a plurality of circuit elements having the same function, such as the RF amplifier section 21 and the mixer section 22, but different in noise characteristic or linearity, are prepared. By switching between the circuit elements to switch into a circuit element different in distortion characteristic or noise characteristic, the quantity of errors to be generated when the IF signal is generated in the tuner 2 may be decreased. By switching between the circuit elements as described above, a control is possible in which, for example, errors to be included in the signal Sd due to a change in an operation parameter of a circuit element after switching are less than errors to be included in the signal Sd in a circuit element before switching.

Next, a third circuit element and the quantity of a change in an operation parameter of the third circuit element are determined such that the operation parameter of the second circuit element is returned to that before the change. For example, the RF amplifier section 21 is selected as the third circuit element, and the quantity of a change in an operation parameter of the third circuit element is determined such that the status of the RF amplifier section 21 is returned to the status before an operation parameter is changed to increase the gain. Because the status of the third circuit element is returned from the status in which the power consumption has increased, to the status before the power consumption increases, the quantity of an increase in the power consumption can be suppressed to the minimum.

Next, the change content determining section 401 determines change timings for operation parameters of the first and second circuit elements, such that the change timing for the second circuit element is temporally precedent to the change timing for the first circuit element by a length not less than a time interleaving length. In addition, the change content determining section 401 determines the change timing for an operation parameter of the third circuit element such that the change timing for the third circuit element is later than the change timing for the first circuit element by a length not less than a time interleaving length.

In this embodiment, the first to third circuit elements may include therein a circuit element in the demodulator 3. As shown in FIG. 4A, a demodulator controlling section 5 is provided in the demodulator 3 to control the circuit element in the demodulator 3. On the basis of the first to third circuit elements, the quantity of a change in an operation parameter, and the change timings, determined by the change content determining section 401 as described above, the tuner controlling section 4 and the demodulator controlling section 5 change the operation parameters of the first to third circuit elements.

In FIG. 7, a curved line 93b represents the quantity of errors to be included in the signal Si before time interleaving by the tuner controlling section 4 and the demodulator controlling section 5 changing the operation parameters of the first to third circuit elements. The signal Si includes therein errors generated in a circuit element that constitutes the digital demodulating apparatus 1. Such errors once decreases by a change 84 in an operation parameter of the second circuit element. A change 85 in an operation parameter of the third circuit element is performed after a change 83 in an operation parameter of the first circuit element, and the quantity of errors included in the signal Si is returned to the status before the change in the operation parameter of the second circuit element.

On the other hand, by a series of changes in operation parameter as described above, errors included in the signal Sd after time deinterleaving are as follows. A curved line 94 represents the quantity of errors after time deinterleaving. First, at a timing T4, the change 84 in an operation parameter of the second circuit element is performed. Thereby, the errors included in the signal Si decreases as described above. The signal in the range in which errors decreases in the signal Si is dispersed by time deinterleaving. Thus, the errors to be included in the signal Sd decreases gradually over the period P2 of a time interleaving length Li as shown by the curved line 94.

Next, at a timing T3 later than the timing T4 by a length not less than a time interleaving length Li, an operation parameter of the first circuit element is changed. Although an error 83 is generated in the signal Si due to the change, the error 83 is dispersed over the period P1 of a time interleaving length Li in the signal Sd after time deinterleaving. However, because of the change 84 in the operation parameter temporally precedent to the timing T3 by a length not less than a time interleaving length Li, errors have sufficiently decreased in the signal Sd at the timing T3. Thus, the total quantity of errors in the period P1 is smaller than that in the case of no change 84.

Next, at a timing T5 later than the timing T3 by a length not less than a time interleaving length, a change 85 in the operation parameter of the third circuit element is performed. Thereby, the quantity of errors included in the signal Si is returned to the value before the change 84 in the operation parameter of the second circuit element. Therefore, like the above, because affection to increase the quantity of errors is dispersed, the quantity of errors in the signal Sd increases gradually over the period P3.

As described above, the second circuit element, the quantity of a change in an operation parameter of the second circuit element, and a change timing, are determined so that the total quantity of errors included in the signals Si and Sd due to a change in an operation parameter of the first circuit element decreases by changing the operation parameter of the second circuit element, in comparison with a case of no change in the second circuit element.

In addition, the change timings for the operation parameters of the first and second circuit elements are determined such that they are temporally distant from each other by a length not less than a time interleaving length. Thereby, after a sufficient effect of a decrease in errors by the change in the operation parameter of the second circuit element is brought about in the signal Sd, the operation parameter of the first circuit element is performed.

By changing the operation parameter of the third circuit element, the operation parameter of the second circuit element is returned to the status before the change. For example, while the frequency of the mixing signal in the VCO-PLL section 23 is stabilized, the power consumption of the circuit element is higher than that before the stabilization. However, by changing the operation parameter of the third circuit element to return it to the status before the change, the power consumption is also returned to the original status.

In addition, the change timings for the operation parameters of the first and third circuit elements are determined such that they are temporally distant from each other by a length not less than a time interleaving length. Thereby, in the signal Sd, the period in which errors increases due to the change in the operation parameter of the third circuit element does not overlap the period that is occupied by errors generated due to the change in the operation parameter of the first circuit element. That is, after disappearance of affection of errors generated due to the change in the operation parameter of the first circuit element, errors increases due to the change in the operation parameter of the third circuit element.

Also in this embodiment, the change content determining section 401 determines a change timing for an operation parameter such that the timing is at the leading edge of a symbol. This can minimize the number of symbols affected by errors generated due to the change in the operation parameter.

### Third Embodiment

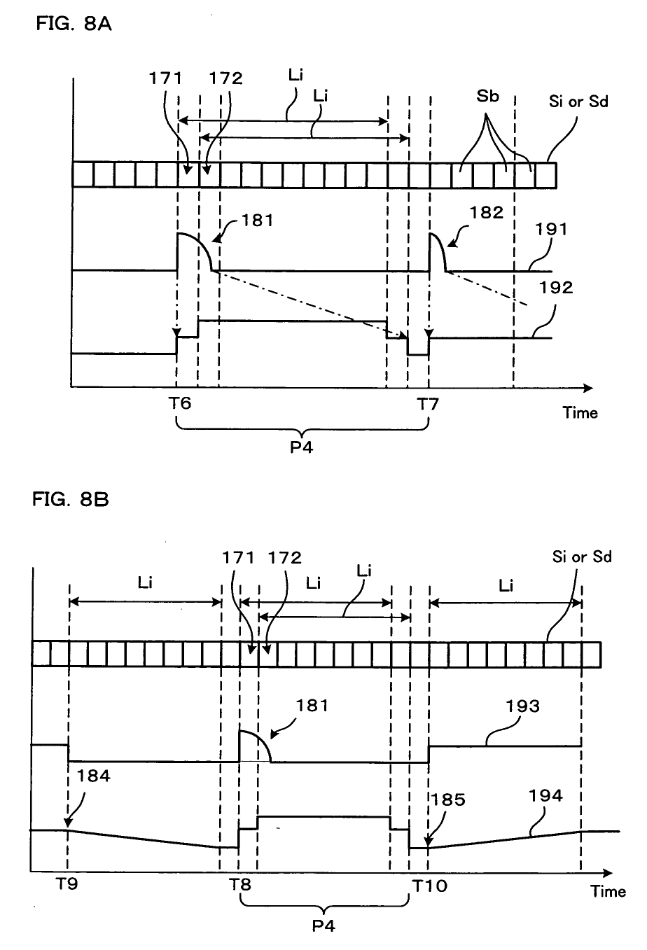

Next, a third embodiment of a change in an operation parameter by the tuner controlling section 4 will be described. FIGS. 8A and 8B show errors generated in the signal Si or the like due to a change in an operation parameter according to the third embodiment. In FIGS. 8A and 8B, an error 181 generated due to a change in an operation parameter is over two symbols 171 and 172. In FIGS. 8A and 8B, curved lines 191 and 193 represent errors generated in the signal Si before time deinterleaving, and curved lines 192 and 194 represent errors generated in the signal Sd after time deinterleaving. The feature of this embodiment is similar to those of the above two embodiments, and thus only the difference from the above two embodiments will be described below.

In the case that an error is generated over a plurality of symbols, as the error 181 of FIGS. 8A and 8B, the error is dispersed beyond a time interleaving length Li after time deinterleaving. The error 181 is generated over two symbols. In this case, the error is dispersed over a period P4 that is longer than a time interleaving length by a length corresponding to one symbol. Thus, in the case of changing operation parameters of two circuit elements as in the above first embodiment, as shown in FIG. 8A, change timings T6 and T7 for the operation parameters of the first and second circuit elements are determined such that they are temporally distant from each other by a length that is longer than a time interleaving length by a length corresponding to not less than one symbol.

On the other hand, in the case of changing an operation parameter to decrease errors in advance as in the above second embodiment, change timings T8, T9, and T10 are determined as shown in FIG. 8B. The timing T9 is the timing of a change 184 in an operation parameter of the second circuit element to decrease errors. The change timing T8 is for an operation parameter of the first circuit element. The timing T10 is the timing of. a change 185 in an operation parameter of the third circuit element to return the operation parameter of the second circuit element to the original value. The timings T8 and T9 are determined such that they are temporally distant from each other by a length not less than a time interleaving length. The change timings T8 and T10 are then determined such that they are temporally distant from each other longer than a time interleaving length by a length corresponding to not less than one symbol.

In the case that an error generated due to a change in an operation parameter is over three or more symbols, a change timing for an operation parameter is determined in accordance with a range in which the error is dispersed by time deinterleaving. The digital demodulating apparatus 1 may have a construction so that the tuner controlling section 4 judges how many symbols an error is generated over due to a change in an operation parameter, and determines a change timing for the operation parameter in accordance with the number of symbols over which the error is.

[Modifications]

Next, modifications of the embodiments of the present invention will be described.

In the above-described embodiments, errors are dispersed by time deinterleaving. However, the present invention may be applied to a case wherein errors are dispersed by block deinterleaving. In such a case, the digital demodulating apparatus 1 may have a construction so that each change timing for an operation parameter is determined such that the ranges in which errors are dispersed by block deinterleaving do not overlap each other. Differently from time deinterleaving, a plurality of fixed regions separating the signal Sr are set in the case of block deinterleaving. Errors of symbols included in each fixed region is dispersed in the fixed region. Thus, if changing an operation parameter is performed in each fixed region not more than one time, errors due to the changes in the operation parameter never overlap.

In the above-described embodiments, the demodulator controlling section 5 is provided in the demodulator 3. However, it may be provided in a portion other than the tuner 2 and the demodulator 3. Or, a controller having the functions of both of the tuner controlling section 4 and the demodulator controlling section 5 may be provided in a portion other than the tuner 2 and the demodulator 3, so that the controller can control both the tuner 2 and the demodulator 3.

In the above embodiment, a change in an operation parameter is mainly described to decrease the quantity of errors generated in the tuner 2. However, the digital demodulating apparatus 1 may have a construction in which the error correction performance of the error correcting section 36 of the demodulator 3 is improved to improve the reliability of information obtained from a signal. For example, the digital demodulating apparatus 1 may have a construction in which a change timing for an operation parameter of a first circuit element is sent to the demodulator 2, and errors are corrected in consideration of the change timing upon Viterbi decoding. In this case, the error correcting section 36 can grasp a timing at which errors increases that are to be included in the signal due to a change in an operation parameter of the first circuit element. That is, the error correcting section 36 can grasp a timing at which the reliability of the signal is lowered due to an increase in errors. Viterbi decoding can be performed in consideration of a decrease in reliability of the signal. This can improve the error correction performance of the error correcting section 36.

In the above embodiment, the digital demodulating apparatus is described that mainly deals with digital signals according to the ISDB-T system. When the present invention is applied to a digital demodulating apparatus that deals with digital signals according to another transmission system than the ISDB-T system, technical terms applied mainly to the ISDB-T system in the above-described embodiment may be replaced by those corresponding to the respective technical terms in the other transmission system than the ISDB-T system. For example, in the above-described embodiment, the detecting section 35 takes out TMCC information from the received signal. In the case of another transmission system, however, a digital demodulating apparatus may have a feature that information corresponding to TMCC information on the signal transmission system is taken out from the received signal.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

What is claimed is:

1. A digital demodulating apparatus comprising:
a plurality of circuit elements that constitute a tuner that performs channel select processing to a received signal that has been interleaved, and a demodulator that performs demodulation processing to the received signal from the tuner;
a deinterleaving section that performs deinterleave processing to the interleaved received signal from the tuner; and
a parameter controlling section that changes the value of an operation parameter that regulates an operation of at least one of the plurality of circuit elements,
the parameter controlling section determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section,
the parameter controlling section then changing the operation parameters of the determined first and second circuit elements by the determined quantities of changes in the first and second operation parameters at the determined change timings for the first and second operation parameters.

2. The apparatus according to claim 1, wherein deinterleave processing to be performed by the deinterleaving section is time deinterleave processing, and
the parameter controlling section determines the change timings for the first and second operation parameters such that the change timing for the first operation parameter is temporally distant from the change timing for the second operation parameter by a length not less than a time interleaving length.

3. The apparatus according to claim 1, wherein the parameter controlling section is provided in the tuner, and
the tuner receives from the demodulator information on effective symbol length and information on time interleaving length.

4. The apparatus according to claim 1, wherein the parameter controlling section determines the first and second circuit elements, the quantities of changes in the first and second operation parameters, and the change timings for the first and second operation parameters, such that the change timing for the second operation parameter is temporally precedent to the change timing for the first operation parameter, and the total quantity of errors to be included in the received signal due to the change in the operation parameter of the first circuit element decreases by the change in the operation parameter of the second circuit element.

5. The apparatus according to claim 1, wherein the parameter controlling section determines the first circuit element, the quantity of change in the first operation parameter, and the change timing for the first operation parameter, such that a power consumption of the first circuit element after the operation of the first circuit element is changed by the quantity of change in the first operation parameter, decreases in comparison with the power consumption of the first circuit element before the operation of the first circuit element is changed by the quantity of change in the first operation parameter.

6. The apparatus according to claim 1, wherein the parameter controlling section determines the first circuit element, the quantity of change in the first operation parameter, and the change timing for the first operation parameter, such that a range in the received signal that is occupied by errors generated due to the change in the first operation parameter of the first circuit element by the quantity of change in the first operation parameter, falls within one symbol included in the received signal before deinterleave processing by the deinterleaving section.

7. The apparatus according to claim 6, wherein the parameter controlling section is provided in the tuner,
the demodulator comprises a symbol synchronization obtaining section that obtains synchronization of a symbol included in the received signal, and
the tuner receives from the demodulator information on the synchronization of the symbol obtained by the symbol synchronization obtaining section.

8. The apparatus according to claim 1, wherein the parameter controlling section determines the change timing for the first operation parameter such that the operation parameter of the first circuit element is changed at a leading edge of a symbol included in the received signal.

9. The apparatus according to claim 1, wherein the tuner comprises an RF amplifier section, a mixer section, a filter section, an IF amplifier section, and a VCO-PLL section, each of which comprises a plurality of circuit elements, and
the parameter controlling section selects at least one of the first and second circuit elements out of the circuit elements included in the RF amplifier section, the mixer section, the filter section, the IF amplifier section, and the VCO-PLL section.

10. The apparatus according to claim 9, wherein the parameter controlling section determines the second circuit element, the quantity of change in the second operation parameter, and the change timing for the second operation parameter, such that noises generated in the received signal in any of the RF amplifier section, the mixer section, the filter section, the IF amplifier section, and the VCO-PLL section, are decreased due to the change in the operation parameter of the second circuit element by the quantity of change in the second operation parameter by the operation parameter controlling section.

11. The apparatus according to claim 10, wherein the parameter controlling section determines the second circuit element, the quantity of change in the second operation parameter, and the change timing for the second operation parameter, such that the distortion characteristic of one of the RF amplifier section, the mixer section, the filter section, the IF amplifier section, and the VCO-PLL section, is improved due to the change in the operation parameter of the second circuit element by the quantity of change in the second operation parameter.

12. The apparatus according to claim 10, wherein the operation parameter of the second circuit element is electric power to be supplied to the second circuit element.

13. The apparatus according to claim 9, wherein the parameter controlling section determines the second circuit element, the quantity of change in the second operation parameter, and the change timing for the second operation parameter, such that a gain of one of the RF amplifier section and the IF amplifier section is increased due to the change in the operation parameter of the second circuit element by the quantity of change in the second operation parameter.

14. The apparatus according to claim 9, wherein the parameter controlling section determines the second circuit element, the quantity of change in the second operation parameter, and the change timing for the second operation parameter, such that a mixing signal generated by the VCO-PLL section is stable in frequency due to the change in the operation parameter of the second circuit element by the quantity of change in the second operation parameter.

15. The apparatus according to claim 1, wherein the first circuit element determined by the parameter controlling section differs in scale from the second circuit element determined by the parameter controlling section.

16. The apparatus according to claim 1, wherein the parameter controlling section determines a third circuit element of the plurality of circuit elements, the quantity of change in a third operation parameter of the third circuit element, and a change timing for the third operation parameter of the third circuit element, such that
ranges each of which is occupied by errors to be generated in the received signal by changing the operation parameters of the first and third circuit elements at the change timings for the first and third operation parameters, do not overlap each other in the received signal deinterleaved by the deinterleaving section, and
ranges each of which is occupied by errors to be generated in the received signal by changing the operation parameters of the second and third circuit elements at the change timings for the second and third operation parameters, do not overlap each other in the received signal deinterleaved by the deinterleaving section, and
the parameter controlling section changes the operation parameters of the determined first to third circuit elements by the determined quantities of change in the first to third operation parameters at the determined change timings for the first to third operation parameters.

17. The apparatus according to claim 16, wherein deinterleave processing to be performed by the deinterleaving section is time deinterleave processing, and
the parameter controlling section determines the change timings for the first and second operation parameters such that the change timings for the first to third operation parameters are temporally distant from one another by a length not less than a time interleaving length.

18. The apparatus according to claim 16, wherein the parameter controlling section determines the first to third circuit elements, the quantities of change in the first to third operation parameters, and the change timings for the first to third operation parameters, such that
(a) the change timings for the first to third operation parameters are temporally arranged in the order of the second, first, and third operation parameters;
(b) the total quantity of errors to be included in the received signal due to the changes in the operation parameters of both of the first and second circuit elements, is smaller than the total quantity of errors to be included in the received signal due to the change in the operation parameter of only the first circuit element; and
(c) the operation parameter of the first circuit element is returned to the operation parameter before the operation parameter of the first circuit element is changed, by changing the operation parameter of the third circuit element.

19. A controlling method of a digital demodulating apparatus comprising a plurality of circuit elements that constitute a tuner that performs channel select processing to a received signal that has been interleaved, and a demodulator that performs demodulation processing to the received signal from the tuner; and a deinterleaving section that performs deinterleave processing to the interleaved received signal from the tuner,
the method comprising:
a determining step of determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section; and
a parameter changing step of changing the operation parameters of the first and second circuit elements determined in the changing step, by the quantities of changes in the first and second operation parameters determined in the changing step, at the change timings for the first and second operation parameters determined in the changing step.

20. A computer program product for a digital demodulating apparatus comprising a plurality of circuit elements that constitute a tuner that performs channel select processing to a received signal that has been interleaved, and a demodulator that performs demodulation processing to the received signal from the tuner; and a deinterleaving section that performs deinterleave processing to the interleaved received signal from the tuner,
the product causing the digital demodulating apparatus to execute:
a determining step of determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section; and
a parameter changing step of changing the operation parameters of the first and second circuit elements determined in the changing step, by the quantities of changes in the first and second operation parameters determined in the changing step, at the change timings for the first and second operation parameters determined in the changing step.

21. A computer-readable recording medium recording thereon a computer program product for a digital demodulating apparatus comprising a plurality of circuit elements that constitute a tuner that performs channel select processing to a received signal that has been interleaved, and a demodulator that performs demodulation processing to the received signal from the tuner; and a deinterleaving section that performs deinterleave processing to the interleaved received signal from the tuner,
the product causing the digital demodulating apparatus to execute:
a determining step of determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section; and
a parameter changing step of changing the operation parameters of the first and second circuit elements determined in the changing step, by the quantities of changes in the first and second operation parameters determined in the changing step, at the change timings for the first and second operation parameters determined in the changing step.

22. A digital receiver comprising a digital demodulating apparatus comprising:
a plurality of circuit elements that constitute a tuner that performs channel select processing to a received signal that has been interleaved, and a demodulator that performs demodulation processing to the received signal from the tuner;
a deinterleaving section that performs deinterleave processing to the interleaved received signal from the tuner; and
a parameter controlling section that changes the value of an operation parameter that regulates an operation of at least one of the plurality of circuit elements,
the parameter controlling section determining first and second circuit elements of the plurality of circuit elements, the quantities of changes in first and second operation parameters of the first and second circuit elements, and change timings for the first and second operation parameters of the first and second circuit elements, such that ranges each of which is occupied by errors to be generated in the received signal by changing the quantities of the operation parameters of the first and second circuit elements at the change timings for the first and second operation parameters, do not overlap each other in the received signal deinterleaved by the deinterleaving section,
the parameter controlling section then changing the operation parameters of the determined first and second circuit elements by the determined quantities of changes in the first and second operation parameters at the determined change timings for the first and second operation parameters,
the receiver performing reproduction processing for at least one of character data, image data, audio data, and program data, on the basis of the received signal demodulated by the digital demodulating apparatus.
